(19) United States
(12) Patent Application Publication
(10) Pub. No.: US 2021/0265128 A1
(43) Pub. Date: Aug. 26, 2021

(54) SPECIMEN MOUNTS AND RELATED METHODS

(71) Applicant: Battelle Energy Alliance, LLC, Idaho Falls, ID (US)

(72) Inventor: Alexander J. Winston, Idaho Falls, ID (US)

(21) Appl. No.: 16/947,072

(22) Filed: Jul. 16, 2020

Related U.S. Application Data
(60) Provisional application No. 62/981,959, filed on Feb. 26, 2020.

(51) Int. Cl. H01J 37/20; H01J 37/28

(52) U.S. Cl. CPC H01J 37/20; H01J 2237/2007; H01J 37/28

(57) ABSTRACT

A specimen mount may include a pin stub and a base member. The pin stub may be sized and configured for mounting in an inspection device. The base member may be sized and configured for mounting in a polishing machine. The base member may include a coupler sized and configured to receive the pin stub and couple the pin stub to the base member. A method of preparing a specimen may comprise positioning the specimen on a pin stub and coupling the pin stub to the base member. The base member with the pin stub and specimen may then be positioned in a polishing machine. A method of manufacturing a specimen mount may comprise forming a base member sized and configured for mounting in a polishing machine, and forming a coupler in the base member sized and configured to receive a pin stub.

### CROSS-REFERENCE TO RELATED APPLICATION

This application claims the benefit of U.S. Provisional Patent Application Ser. No. 62/981,959, filed Feb. 26, 2020, and entitled “Recessed SEM pin stub sample mount for metallographic preparation and microanalysis via various numerous methods,” the disclosure of which is hereby incorporated herein in its entirety by this reference.

### STATEMENT REGARDING FEDERALLY SPONSORED RESEARCH OR DEVELOPMENT

This invention was made with government support under Contract Number DE-AC07-05-1D14517 awarded by the United States Department of Energy. The government has certain rights in the invention.

### FIELD

Embodiments of the disclosure relate generally to specimen mounts. More particularly, embodiments of the disclosure relate to specimen mounts that facilitate both the preparation and inspection of a specimen mounted thereon, and related methods.

### BACKGROUND

Metallographic mounts have been standardized for use in polishing machines. The standardization of mount size is convenient for using a mount on various polishing machines. The standard mount size for polishing machines, however, is not convenient for use in many inspection devices, such as a scanning electron microscope (SEM). For example, the mount may not be easily installed and may be too large, causing mechanical interference with components of the inspection device.

To study a specimen, it is often necessary or desirable to polish the specimen before inspection. Accordingly, the specimen may be adhered to a mount with epoxy for polishing. After polishing with a polishing machine the specimen may be ready for inspection. However, because standard mounts for polishing machines are inconvenient or unsuitable for some inspection operations, the specimen may need to be remounted.

The remounting process typically involves cutting the specimen free from the epoxy and remounting the specimen on another mount, such as an SEM stub. Not only is this remounting process inconvenient, it can cause damage to the specimen. For example, it may be difficult to maintain the surface finish of the specimen during the remounting process. Additionally, the remounting process may be further complicated when working with radiological specimens, which may require working with manipulators in a hot cell environment. Accordingly, improvements in specimen mounting, preparation, and inspection would be desirable.

### BRIEF SUMMARY

In accordance with embodiments described herein, a specimen mount may include a pin stub and a base member. The pin stub may be sized and configured for mounting in an inspection device. The base member may be sized and configured for mounting in a polishing machine. The base member may include a coupler sized and configured to receive the pin stub and couple the pin stub to the base member.

In additional embodiments, a method of preparing a specimen may comprise positioning the specimen on a pin stub configured for mounting in an inspection device. The pin stub may be coupled to the base member, and the base member with the pin stub and specimen may be positioned in a polishing machine.

In further embodiments, a method of manufacturing a specimen mount may comprise forming a base member sized and configured for mounting in a polishing machine. The method may further comprise forming a coupler in the base member sized and configured to receive a pin stub and couple the pin stub to the base member.

### BRIEF DESCRIPTION OF THE SEVERAL VIEWS OF THE DRAWINGS

FIG. 1A shows an exploded isometric view of a specimen mount according to an embodiment of the present disclosure.

FIG. 1B shows a transparent exploded isometric view of the specimen mount of FIG. 1A.

FIG. 2A shows an exploded isometric view of another specimen mount according to an embodiment of the present disclosure.

FIG. 2B shows a transparent exploded isometric view of the specimen mount of FIG. 2A.

FIG. 2C shows a transparent exploded side view of the specimen mount of FIG. 2A.

### DETAILED DESCRIPTION

The following description provides specific details, such as material types, dimensions, and processing conditions in order to provide a thorough description of embodiments of the disclosure. However, a person of ordinary skill in the art will understand that the embodiments of the disclosure may be practiced without employing these specific details. Indeed, the embodiments of the disclosure may be practiced in conjunction with conventional fabrication techniques employed in the industry. Only those process acts and structures necessary to understand the embodiments of the disclosure are described in detail below. Also note, any drawings accompanying the present application are for illustrative purposes only, and are thus not drawn to scale. Additionally, elements common between figures may retain the same numerical designation.

As used herein, the terms “comprising,” “including,” “having,” and grammatical equivalents thereof are inclusive or open-ended terms that do not exclude additional, unrecited elements or method steps, but also include the more restrictive terms “consisting of” and “consisting essentially of” and grammatical equivalents thereof. As used herein, the term “may” with respect to a material, structure, feature, or method act indicates that such is contemplated for use in implementation of an embodiment of the disclosure and such term is used in preference to the more restrictive term “is” so as to avoid any implication that other, compatible materials, structures, features, and methods usable in combination therewith should or must be excluded.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the term “configured” refers to a size, shape, material composition, orientation, and arrangement of one or more of at least one structure and at least one apparatus facilitating operation of one or more of the structure and the apparatus in a pre-determined way.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

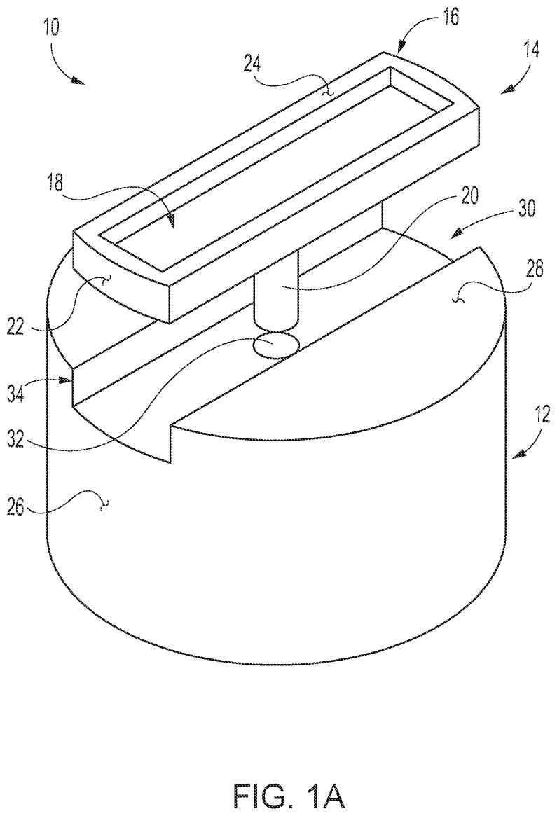

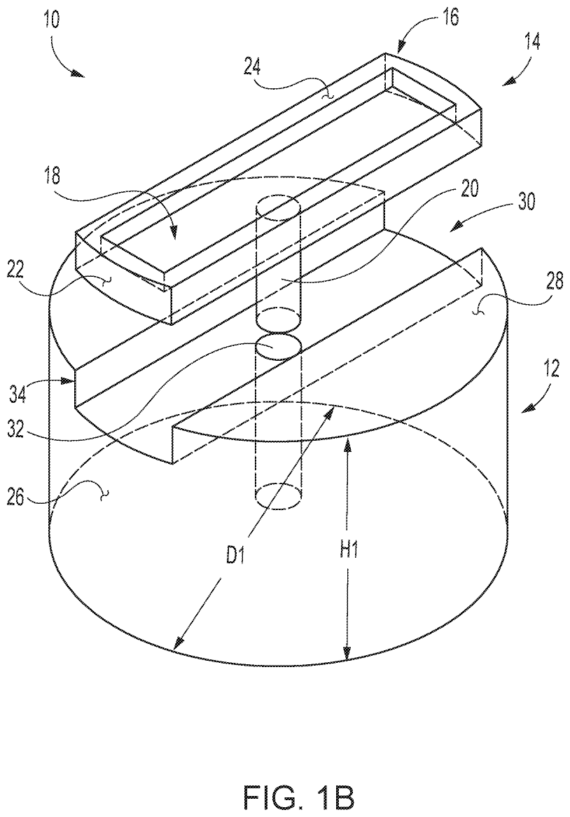

FIGS. 1A-1B show solid and transparent isometric exploded views of a specimen mount 10 according to an embodiment of the present disclosure. The specimen mount 10 may include a base member 12 and a pin stub 14. The pin stub 14 may be sized and configured for mounting in an inspection device, such as a scanning electron microscope (SEM). The pin stub 14 may comprise a specimen platform 16 comprising a cavity 18 configured for receiving a specimen therein, and a pin 20 extending from the specimen platform 16. The pin stub 14 may have an outer surface comprising at least one arcuate outer surface 22, and an upper surface 24, which may be substantially planar.

The base member 12 may have a generally cylindrical shape with an outer surface comprising an arcuate side surface 26 and an upper surface 28, which may be substantially planar. Accordingly, the base member 12 may be sized and configured for mounting in a polishing machine. In some embodiments, the base member 12 may have an outer diameter D1 of about 1.25 inches (about 31.75 mm) and a height H1 of about 0.75 inches (about 19.05 mm). In further embodiments, the base member 12 may have an outer diameter D1 of about 1 inch (about 25.4 mm) and a height H1 of about 0.75 inches (about 19.05 mm). The base member 12 comprises a coupler 30 sized and configured to receive the pin stub 14 and couple the pin stub 14 to the base member 12. The coupler 30 of the base member 12 may comprise an aperture 32 sized and configured to receive the pin 20 of the pin stub 14, and a cavity 34 sized to receive the specimen platform 16 of the pin stub 14.

When the pin stub 14 is coupled to the base member 12 via the coupler 30, an upper surface 24 of the pin stub 14 may be substantially coplanar to an upper surface 28 of the base member 12. Additionally, the at least one arcuate outer surface 22 of the specimen platform 16 may have a radius of curvature substantially the same as a radius of curvature of the arcuate side surface 26 of the base member 12. When the pin stub 14 is coupled to the base member 12 via the coupler 30 the at least one arcuate outer surface 22 of the specimen platform 16 may be substantially aligned with the arcuate side surface 26 of the base member 12.

When the pin stub 14 is inserted into the coupler 30 of the base member 12, the at least one arcuate outer surface 22 of the pin stub 14 may facilitate the grasping of the pin stub 14 for removal of the pin stub 14 from the base member 12. Additionally, the aperture 32 may extend through the bottom of the base member, which may facilitate the removal of the pin stub 14 from the base member 12. For example, a tool, such as a rod, may be inserted into the aperture 32 through the bottom of the base member 12, which may push the pin of the pin stub 14 out of the aperture 32.

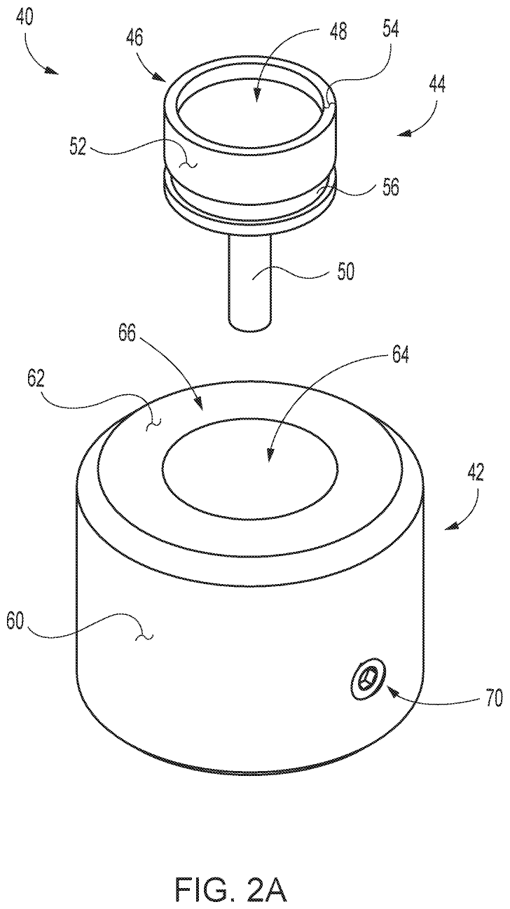

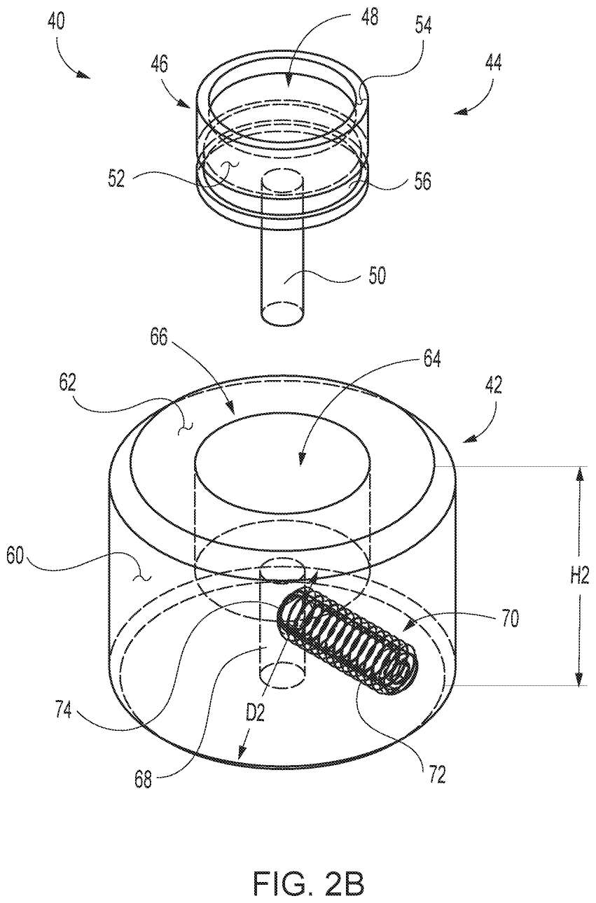

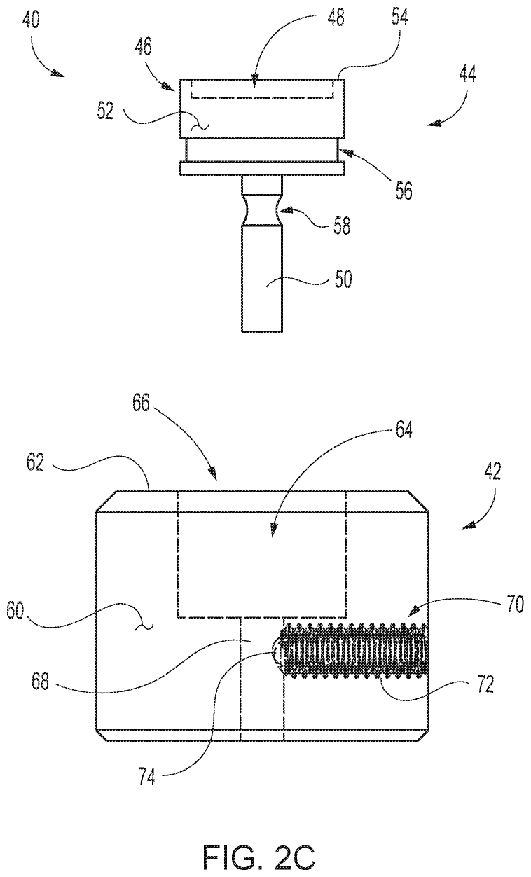

FIGS. 2A-2B show solid and transparent isometric exploded views of a specimen mount 40 according to another embodiment of the present disclosure. The specimen mount 40 includes a base member 42 and a pin stub 44. The pin stub 44 may be sized and configured for mounting in an inspection device, such as an SEM. The pin stub 44 may comprise a specimen platform 46 comprising a cavity 48 configured for receiving a specimen therein, and a pin 50 extending from the specimen platform 46. The specimen platform 46 of the pin stub 44 may have a generally cylindrical shape with an outer surface comprising an arcuate outer surface 52, and an upper surface 54, which may be substantially planar. The specimen platform 46 of the pin stub 44 may include a radially extending groove 56 formed in the arcuate outer surface 52, which may facilitate the handling of the specimen platform 46 with a tool, such as tweezers.

Similar to the base member 12, the base member 42 may have a generally cylindrical shape with an outer surface comprising an arcuate side surface 60 and an upper surface 62, which may be substantially planar. Accordingly, the base member 42 may be sized and configured for mounting in a polishing machine. In some embodiments, the base member 42 may have an outer diameter D2 of about 1.25 inches (about 31.75 mm) and a height H2 of about 0.75 inches (about 19.05 mm). In further embodiments, the base member 42 may have an outer diameter D2 of about 1 inch (about 25.4 mm) and a height H2 of about 0.75 inches (about 19.05 mm). The base member 42 comprises a coupler 66 sized and configured to receive the pin stub 44 and couple the pin stub 44 to the base member 42. The coupler 66 of the base member 42 may comprise an aperture 68 sized and configured to receive the pin 50 of the pin stub 44, and a cavity 64 sized to receive the specimen platform 46 of the pin stub 44.

As shown in a transparent side view in FIG. 2C, a retention device, such as a spring-loaded ball detent 70 in a radial bore or a set screw in a threaded radial bore, may be positioned within a threaded opening 72 extending from the arcuate side surface 60 to the aperture 52 of the base member 42. The pin 50 of the pin stub 44 may optionally comprise a radially extending groove 58 which may facilitate the retaining of the pin stub 44 within the base member 42 with the ball detent 70. The ball detent 70 may be positioned such that a portion of a ball 74 of the ball detent 70 extends into the aperture 68 of the base member, yet the ball 74 is retained in a radially extending bore as the mouth of the bore opening onto aperture 68 is smaller than a diameter of the ball. Accordingly, the ball 74 of the ball detent 70 may be biased into contact with the pin 50 of the pin stub 44 by a spring member, for example, a coil spring, Belleville spring or elastomeric member when the pin 50 is positioned within the aperture 68 of the base member 42. For embodiments wherein the pin 50 comprises a radially extending groove 58, such as shown in FIG. 2C, the spring member of the ball detent 70 may be positioned and configured to bias the ball 74 into the radially extending groove 58 when the pin 50 is positioned within the aperture 68 of the base member 42 to retain the pin stub 44 in the coupler 66 of the base member 42. For embodiments where a set screw is employed, the set screw may be advanced into contact with the radially extending groove 58 to lock pin stub 44 in position, and the set screw backed off using, for example, an Allen wrench, to release pin stub 44.

When the pin stub 44 is coupled to the base member 42 via the coupler 66, the upper surface 54 of the pin stub 44 may be substantially coplanar to an upper surface 62 of the base member 42. Additionally, the arcuate outer surface 52 of the specimen platform 46 may be aligned with and in contact with a surface of the cavity 64 of the base member 42, when the pin stub 44 is coupled to the base member 42 via the coupler 66.

The aperture 68 may extend through the bottom of the base member 42, which may facilitate the removal of the pin stub 44 from the base member 42. For example, a tool, such as a rod, may be inserted into the aperture 68 through the bottom of the base member 42, which may push the pin 50 of the pin stub 44 out of the aperture 68.

A specimen mount 10, 40 according to embodiments of the present disclosure may be manufactured by forming a base member 12, 42 sized and configured for mounting in a polishing machine. For example, the base member 12, 42 may be machined from a material such as brass, aluminum, steel, or another suitable metal or metal alloy. A coupler 30, 66 may be formed in the base member 12, 42, the coupler 30, 66 sized and configured to receive a pin stub 14, 44 therein and to couple the pin stub 14, 44 to the base member 12, 42. Optionally, a threaded opening 72 may be formed in the base member 12, 42 and a retaining device, such as a ball detent 70 or a set screw, may be positioned in the threaded opening 72 of the base member 12, 42 to retain the pin stub 14, 44 in the base member 12, 42 when the pin stub 14, 44 is coupled to the base member 12, 42. The pin stub 14, 44 may be manufactured to include a pin 20, 50 sized for insertion into an inspection device, such as an SEM. Additionally, the pin stub 14, 44 may be manufactured to include a specimen platform 16, 46 sized and configured for mounting a specimen of a specific size and shape.

In use, a specimen may be prepared by positioning the specimen on a pin stub 14, 44 configured for mounting in an inspection device. An adhesive, such as an epoxy, may be the positioned within the cavity 18, 48 of the pin stub 14, 44, and the specimen may be positioned in the adhesive within the cavity 18, 48. The adhesive may then be allowed to cure or set to fix the specimen to the specimen platform 16, 46 of the pin stub 14, 44.

After the specimen has been secured to the specimen platform 16, 46 of the pin stub 14, 44, the pin sub 14, 44 may be inserted into the coupler 30, 66 of the base member 12, 42 to couple the pin stub 14, 44 to the base member 12, 42. For example, a pin 20, 50 of the pin stub 14, 44 may be inserted into an aperture 32, 68 in the base member 12, 42 and the pin stub 14, 44 may be retained in the base member 12, 42 with a friction fit between the pin stub 14, 44 and the base member 12, 42. Optionally, the pin stub 14, 44 may be retained in the base member 12, 42 with a retaining device, such as a ball detent 70 or set screw. When the pin sub 14, 44 is inserted into the coupler 30, 66 of the base member 12, 42 an outer surface of the pin stub 14, 44 may be aligned with an outer surface of the base member 12, 42. The upper surface 24, 54 of the pin stub 14, 44 may be aligned with the upper surface 28, 62 of the base member 12, 42. Additionally, an arcuate side surface 22 of the pin stub 14 may be aligned with an arcuate side surface 26 of the base member 12.

The base member 12, 42 with the pin stub 14, 44 having the specimen mounted thereon may be inserted into a polishing machine and the specimen may be polished. Optionally, the polishing machine may be utilized to polish the specimen to have a polished surface substantially coplanar to the upper surface 24, 54 of the pin stub 14, 44 and the upper surface 28, 62 of the base member 12, 42, and may even incidentally polish the upper surface 24, 54 of the pin stub 14, 44 and the upper surface 28, 62 of the base member 12, 42 along with the specimen. In view of this, aligning the upper surface 24, 54 of the pin stub 14, 44 and the upper surface 28, 62 of the base member 12, 42 to be substantially coplanar may facilitate the preparation of the specimen by the polishing machine.

After the specimen is polished in the polishing machine, the base member 12, 42 with the pin stub 14, 44 having the specimen mounted thereon may be inserted directly into an inspection device. Additionally, the pin stub 14, 44 and specimen may be removed from the base member 12, 42, such as by inserting a tool into the aperture 32, 68 of the base member 12, 42 and/or grasping the at least one arcuate outer surface 22 of the pin stub 14, and then inserted into an inspection device. If the surface of the specimen is damaged during handling and/or during an inspection process, the pin stub 14, 44 having the specimen mounted thereon may be reinstalled into the base member 12, 42 and the base member 12, 42 with the pin stub 14, 44 having the specimen mounted thereon may be inserted into a polishing machine and the specimen may be polished again and prepared for further inspection.

While embodiments of the disclosure may be susceptible to various modifications and alternative forms, specific embodiments have been shown by way of example in the drawings and have been described in detail herein. However, it should be understood that the disclosure is not limited to the particular forms disclosed. Rather, the disclosure encompasses all modifications, variations, combinations, and alternatives falling within the scope of the disclosure as defined by the following appended claims and their legal equivalents.

What is claimed is:

1. A specimen mount comprising:
a pin stub sized and configured for mounting in an inspection device; and
a base member sized and configured for mounting in a polishing machine, the base member comprising a coupler sized and configured to receive the pin stub and couple the pin stub to the base member.

2. The specimen mount of claim 1, wherein the pin stub comprises:
a specimen platform sized and configured for mounting a specimen; and
a pin extending from the specimen platform.

3. The specimen mount of claim 2, wherein the specimen platform comprises a cavity configured for receiving a specimen therein.

4. The specimen mount of claim 2, wherein the base member comprises an aperture sized and configured to receive the pin of the pin stub.

5. The specimen mount of claim 4, wherein the base member comprises a ball detent positioned such that a portion of a ball of the ball detent is biased to extend into the aperture or a set screw adjustable in a threaded radial bore to extend into the aperture.

6. The specimen mount of claim 5, wherein the ball of the ball detent is biased into contact with the pin of the pin stub when the pin is positioned within the aperture of the base member.

7. The specimen mount of claim 6, wherein the pin of the pin stub comprises a radially extending groove and wherein the ball detent is configured to bias the ball into the radially extending groove when the pin is positioned within the aperture of the base member.

8. The specimen mount of claim 4, wherein an upper surface of the pin stub is substantially coplanar to an upper surface of the base member when the pin stub is coupled to the base member.

9. The specimen mount of claim 4, wherein the base member has a generally cylindrical shape.

10. The specimen mount of claim 9, wherein the specimen platform of the pin stub comprises at least one arcuate outer surface having a radius of curvature substantially the same as a radius of curvature of an outer surface of the base member, and wherein the at least one arcuate outer surface of the specimen platform is substantially aligned with the outer surface of the base member.

11. The specimen mount of claim 1, wherein the pin stub is configured for mounting in a scanning electron microscope.

12. A method of preparing a specimen, the method comprising:
positioning the specimen on a pin stub configured for mounting in an inspection device;
coupling the pin stub to a base member; and
positioning the base member with the pin stub and specimen in a polishing machine.

13. The method of claim 12, wherein coupling the pin stub to the base member comprises inserting a pin of the pin stub into an aperture in the base member.

14. The method of claim 13, further comprising retaining the pin stub in the base member with a friction fit between the pin stub and the base member.

15. The method of claim 13, further comprising retaining the pin stub in the base member with a spring-biased ball detent or a set screw.

16. The method of claim 13, further comprising aligning an outer surface of the pin stub with an outer surface of the base member.

17. The method of claim 16, wherein aligning the outer surface of the pin stub with the outer surface of the base member comprises aligning an upper surface of the pin stub with an upper surface of the base member.

18. The method of claim 16, wherein aligning the outer surface of the pin stub with the outer surface of the base member further comprises aligning an arcuate side surface of the pin stub with an arcuate side surface of the base member.

19. A method of manufacturing a specimen mount, the method comprising:
forming a base member sized and configured for mounting in a polishing machine; and
forming a coupler in the base member sized and configured to receive a pin stub and couple the pin stub to the base member.

20. The method of claim 19, further comprising positioning a ball detent or a set screw in the base member to retain the pin stub in the base member when the pin stub is coupled to the base member.
